(19) United States
(12) Patent Application Publication
(10) Pub. No.: US 2022/0045249 A1
(43) Pub. Date: Feb. 10, 2022

(54) OPTOELECTRONIC SEMICONDUCTOR COMPONENT HAVING A FIRST AND SECOND METAL LAYER AND METHOD FOR PRODUCING THE OPTOELECTRONIC SEMICONDUCTOR COMPONENT

(71) Applicant: OSRAM OLED GmbH, Regensburg (DE)

(72) Inventors: Christian Eichinger, Wenzenbach (DE); Korbinian Perzlmaier, Regensburg (DE)

(21) Appl. No.: 17/275,672

(22) PCT Filed: Sep. 12, 2019
(86) PCT No.: PCT/EP2019/074387

§ 371 Date: Mar. 12, 2021

(30) Foreign Application Priority Data
Sep. 14, 2018 (DE) 10 2018 122 492.3

(51) Int. Cl. H01L 33/62; H01L 33/60; H01L 33/00; H01L 33/20

(52) U.S. Cl. CPC H01L 33/62; H01L 33/60; H01L 2933/0066; H01L 33/20; H01L 33/005

(57) ABSTRACT

An optoelectronic semiconductor component may include a first semiconductor layer of a first conductivity type, a second semiconductor layer of a second conductivity type, and an active zone, wherein the first semiconductor layer and the second semiconductor layer are patterned to form a mesa so that parts of the second semiconductor layer are not covered by the first semiconductor layer and a portion of the active zone is exposed in the area of a mesa flank. The optoelectronic semiconductor component may include a passivation layer arranged over parts of the first semiconductor layer and over parts of the second semiconductor layer and over the exposed portion of the active zone. The optoelectronic semiconductor component furthermore contains a first metal layer and a second metal layer. The second metal layer covers the passivation layer in the area of the mesa flank.

### CROSS-REFERENCE TO RELATED APPLICATIONS

The present application is a national stage entry according to 35 U.S.C. § 371 of PCT Application No. PCT/EP2019/074387 filed on Sep. 12, 2019; which claims priority to German Patent Application Serial Nos. 10 2018 122 492.3 filed on Sep. 14, 2018; all of which are incorporated herein by reference in their entirety and for all purposes.

### TECHNICAL FIELD

The present disclosure relates to optoelectronic semiconductor components having a first layer, second layer, and an active zone therebetween where the first layer and the second layer form a mesa so that parts of the second layer are free from the first layer and a portion oft he active zone is exposed in an area of a mesa flank.

### BACKGROUND

A light emitting diode (LED) is a light emitting device based on semiconductor materials. For example, an LED includes a pn junction. When electrons and holes recombine with one another in the area of the pn junction, for example because a corresponding voltage is applied, electromagnetic radiation is generated.

New ways to optimize decoupling efficiency are continually being sought as the miniaturization of optoelectronic semiconductor components progresses.

The object of the present disclosure is to provide an improved optoelectronic component.

### SUMMARY

An optoelectronic semiconductor component comprises a first semiconductor layer of a first conductivity type, a second semiconductor layer of a second conductivity type and an active zone. The first semiconductor layer is arranged over the second semiconductor layer. The active zone is arranged between the first and second semiconductor layers. The first semiconductor layer and the second semiconductor layer are patterned to form a mesa in such a way that parts of the second semiconductor layer are not covered by the first semiconductor layer and a portion of the active zone is exposed in the area of a mesa flank. The optoelectronic semiconductor component furthermore comprises a passivation layer which is arranged over parts of the first semiconductor layer and over parts of the second semiconductor layer and over the exposed portion of the active zone. The optoelectronic semiconductor component also contains a first metal layer which is electrically connected to the first semiconductor layer, and a second metal layer which is electrically connected to the second semiconductor layer. The second metal layer covers the passivation layer in the area of the mesa flank. A composition of the first metal layer adjacent to the first semiconductor layer is constant in a horizontal direction.

A metal of the first or the second metal layer may each be selected from the group consisting of rhodium, platinum, gold, nickel, chromium and palladium. For example, the first or the second metal layer is in each case made of rhodium or palladium.

The first metal layer may directly adjoin the first semiconductor layer. A lateral positioning of the first metal layer may differ by less than 100 nm from the lateral positioning of the patterned first semiconductor layer. According to embodiments, a horizontally extending part of the second metal layer is arranged over the first metal layer.

The optoelectronic semiconductor component may furthermore comprise a metallic mirror layer, which is electrically insulated from the second semiconductor layer and the second metal layer and is arranged over part of the second semiconductor layer.

A metal of the metallic mirror layer may be selected from the group consisting of rhodium, platinum, gold, nickel, chromium and palladium. The metallic mirror layer may be connected to the first metal layer.

For example, the first metal layer may be laterally at least partially surrounded by the second metal layer, the metallic mirror layer or a combination of these layers.

In accordance with further embodiments, an optoelectronic semiconductor component comprises a first semiconductor layer of a first conductivity type, a second semiconductor layer of a second conductivity type and an active zone. The first semiconductor layer is arranged over the second semiconductor layer. The active zone is arranged between the first and second semiconductor layers. The first semiconductor layer and the second semiconductor layer are patterned to form a mesa so that parts of the second semiconductor layer are not covered by the first semiconductor layer and a portion of the active zone is exposed in the area of a mesa flank. The optoelectronic semiconductor component furthermore comprises a passivation layer which is arranged over parts of the first semiconductor layer and over parts of the second semiconductor layer, as well as over the exposed portion of the active zone. The optoelectronic semiconductor component also comprises a first metal layer which is electrically connected to the first semiconductor layer, and a second metal layer which is electrically connected to the second semiconductor layer. The second metal layer covers the passivation layer in the area of the mesa flank. Furthermore, the first metal layer or a metallic mirror layer that is electrically separated from the second metal layer covers the passivation layer in the area of the mesa flank.

A metal of the first or second metal layer may each be selected from the group consisting of rhodium, platinum, gold, nickel, chromium and palladium. For example, a lateral positioning of the first metal layer differs by less than 100 nm from the lateral positioning of the patterned first semiconductor layer.

For example, the metallic mirror layer is connected to the first metal layer.

Furthermore, part of the metallic mirror layer may be arranged over part of the second semiconductor layer.

A lateral size of the optoelectronic semiconductor component described may be less than 70 μm.

A method for producing an optoelectronic semiconductor component comprises forming a semiconductor layer stack comprising a first semiconductor layer of a first conductivity type, a second semiconductor layer of a second conductivity type and an active zone, the active zone being arranged between the first and second semiconductor layers. The method further comprises patterning a mesa so that parts of the second semiconductor layer are not covered by the first semiconductor layer and a portion of the active zone is exposed in the area of a mesa flank. The method further comprises forming a passivation layer over parts of the first semiconductor layer, over parts of the second semiconductor layer and over the exposed portion of the active area, forming a first metal layer that is electrically connected to the first semiconductor layer, and forming a second metal layer that is electrically connected to the second semiconductor layer. The second metal layer covers the passivation layer in the area of the mesa flank. A composition of the first metal layer adjacent to the first semiconductor layer is constant in a horizontal direction.

According to further embodiments, the first metal layer or a metallic mirror layer electrically separated from the second metal layer covers the passivation layer in the area of the mesa flank.

The method may further comprise the etching of a part of the first metal layer, whereby a patterned first metal layer is obtained, and the etching of a part of the first semiconductor layer. The patterned first metal layer may be used as an etching mask for etching the first semiconductor layer.

According to embodiments, an optoelectronic device comprises the optoelectronic semiconductor component described above. The optoelectronic device may be selected from a display device, a lighting device for vehicles or a lighting device.

### BRIEF DESCRIPTION OF THE DRAWINGS

The accompanying drawings serve to provide an understanding of examples of embodiments. The drawings illustrate embodiments and, together with the description, serve to explain them. Further embodiments and numerous intended advantages emerge directly from the following detailed description. The elements and structures shown in the drawings are not necessarily shown true to scale with one another. The same reference numerals refer to the same or corresponding elements and structures.

FIG. 1A shows a vertical cross-sectional view of an example of an optoelectronic semiconductor component according to embodiments.

FIG. 1B shows a top view of an optoelectronic semiconductor component according to embodiments.

FIGS. 2A to 2F are vertical cross-sectional views of a workpiece during production of an optoelectronic semiconductor component according to embodiments.

FIG. 3A is a cross-sectional view for illustrating additional components of the optoelectronic semiconductor device.

FIG. 3B is a top view of an example of an optoelectronic semiconductor device.

FIG. 3C is a top view of an example of an optoelectronic semiconductor device.

FIG. 4A shows a vertical cross-sectional view to illustrate additional components of the optoelectronic semiconductor component.

FIG. 4B is a top view of an example of an optoelectronic semiconductor device.

FIG. 4C is a vertical cross-sectional view of an example of an optoelectronic semiconductor device in accordance with further embodiments.

FIG. 5 shows components of an optoelectronic semiconductor device according to further embodiments.

FIGS. 6A, 6B and 6C each summarize a method according to embodiments.

FIG. 7A shows a schematic view of an optoelectronic device according to embodiments.

FIG. 7B shows a schematic view of an optoelectronic device according to embodiments.

### DETAILED DESCRIPTION

In the following detailed description, reference is made to the accompanying drawings, which form a part of the disclosure and in which specific examples of embodiments are shown for purposes of illustration. In this context, directional terminology such as “top”, “bottom”, “front”, “back”, “over”, “on”, “in front”, “behind”, “leading”, “trailing”, etc. is used related to the alignment of the figures just described. Since the components of the embodiments may be positioned in different orientations, the directional terminology is used for explanation only and is in no way restrictive.

The description of the examples of embodiments is not restrictive, since other embodiments also exist and structural or logical changes may be made without deviating from the range defined by the claims. In particular, elements of the embodiments described below may be combined with elements of the other embodiments described, unless the context indicates otherwise.

The terms “wafer” or “semiconductor substrate” used in the following description may include any semiconductor-based structure that has a semiconductor surface. The wafer and structure are to be understood to include doped and undoped semiconductors, epitaxial semiconductor layers, possibly supported by a base, and further semiconductor structures. For example, a layer of a first semiconductor material may be grown on a growth substrate made of a second semiconductor material or of an insulating material, for example sapphire. Depending on the intended use, the semiconductor may be based on a direct or an indirect semiconductor material. Examples of semiconductor materials particularly suitable for generating electromagnetic radiation include, in particular, nitride semiconductor compounds, by means of which, for example, ultraviolet, blue or long-wave light can be generated, such as GaN, InGaN, AlN, AlGaN and AlGaInN; phosphide semiconductor compounds by means of which, for example, green or longer-wave light can be generated, such as GaAsP, AlGaInP, GaP and AlGaP; and other semiconductor materials such as AlGaAs, SiC, ZnSe, GaAs, ZnO, Ga₂O₃, diamond, hexagonal BN and combinations of the named materials. The stoichiometric ratio of the ternary compounds may vary. Other examples of semiconductor materials may include silicon, silicon germanium, and germanium. In the context of the present description, the term “semiconductor” also includes organic semiconductor materials.

The terms “lateral” and “horizontal”, as used in this description, are intended to describe an orientation or alignment which runs essentially parallel to a first surface of a semiconductor substrate or semiconductor body. This may be, for example, the surface of a wafer or a die or a chip.

The term “vertical” as used in this description is intended to describe an orientation which is essentially perpendicular to the first surface of the semiconductor substrate or semiconductor body.

To the extent that the terms “have”, “contain” and “comprise”, and the like are used, these are open-ended terms that indicate the presence of said elements or features, but do not rule out the presence of additional elements or features. The indefinite articles and the definite articles include both the plural and the singular, unless the context clearly indicates otherwise.

In the context of this description, the term “electrically connected” means a low-ohmic electrical connection between the connected elements. The electrically connected elements do not necessarily have to be directly connected to one another. Further elements may be arranged between electrically connected elements. The term “electrically connected” also includes tunnel contacts between the connected elements.

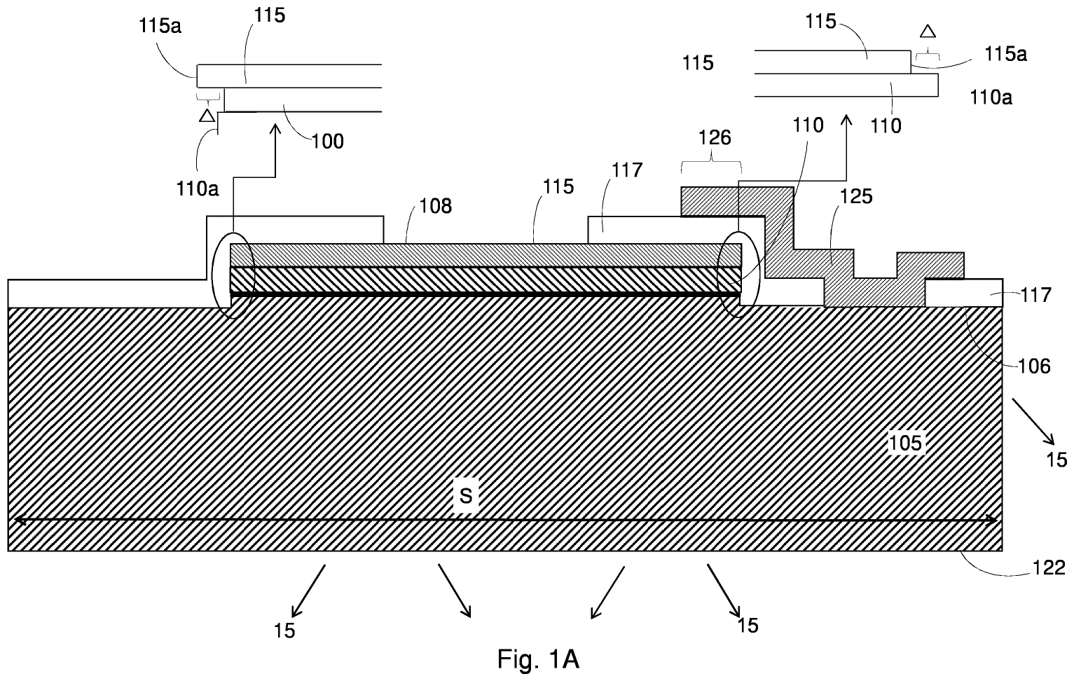

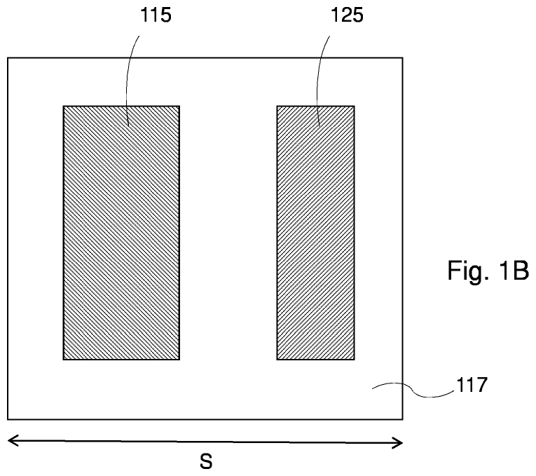

FIG. 1A shows a schematic cross-sectional view through part of an optoelectronic semiconductor component 10 according to embodiments. The optoelectronic semiconductor component comprises a first semiconductor layer 110 of a first conductivity type, for example p-type, and a second semiconductor layer 105 of a second conductivity type, for example n-type. The first semiconductor layer 110 is arranged over the second semiconductor layer 105, for example. The optoelectronic semiconductor component further comprises a first metal layer 115 over the first semiconductor layer 110. The first metal layer 115 is connected to the first semiconductor layer 110 in an electrically conductive manner. A metal of the first metal layer may be selected from the group consisting of rhodium, platinum, palladium, gold, nickel and chromium. Further examples of the metal of the first metal layer 115 include gold, titanium and tantalum. A composition of the first metal layer 115 adjacent to the first semiconductor layer 110 is constant in a horizontal direction. In other words, the first metal layer 115 has a uniform composition in a region adjacent or adjacent to the first semiconductor layer 110. For example, when directly adjacent to or directly adjoining the first semiconductor layer 110 in a horizontal direction, the first metal layer 115 does not comprise varying regions with varying compositions.

The first metal layer 115 may be formed in direct contact with the first semiconductor layer 110. According to further embodiments, for example, adhesion promoting layers may be arranged between the first semiconductor layer 110 and the first metal layer 115. In this context, the term “adjacent to the first semiconductor layer” relates to the part of the first metal layer 115 which, apart from adhesion promoting layers, adjoins the first semiconductor layer 110. In this way, the same metal or the same metal composition is always in contact with the first semiconductor layer 110 in a horizontal direction.

According to embodiments, a lateral positioning of the first metal layer 115 differs by less than 100 nm from the lateral positioning of the conductive layer(s) between first semiconductor layer 110 and first metal layer 115. Examples of materials for adhesion promoting layers include Ti, Cr, Pt, Ni, Ta and WTi, Zn and metal oxides such as ITO (indium tin oxide), IZO (indium zinc oxide) or InO (indium oxide). If a metal from the group consisting of rhodium, platinum, palladium, gold, chromium and nickel is used, the metal layer can be relatively stable, in particular when subjected to moisture, without the necessity of encapsulating the first metal layer 115 for protection against moisture and other environmental influences, according to embodiments. Correspondingly, the first metal layer 115 adjacent to the first semiconductor layer comprises a constant composition in a horizontal direction.

The adhesion promoting layer may, for example, have a layer thickness of more than 0.1 nm or more than 5 nm or more, e.g. 50 nm or more. The metal layer may for example have a layer thickness of more than 50 nm, for example 70 or 80 nm. A rhodium layer, for example is optically dense at thicknesses exceeding around 70 or 80 nm. The layer thickness of the first metal layer 115 may be several hundred nm, for example more than 500 nm. The layer thickness of the metal layer may be selected depending on whether the structured metal layer is used as a hard mask during an etching process in a method for producing the optoelectronic component. Furthermore, the layer thickness may be selected according to whether the metal layer is to be used as a current-carrying layer. For example, an additional adhesion promoting layer made of one of the aforementioned materials may be applied over the first metal layer.

The semiconductor materials used may include, for example, nitride semiconductor materials or phosphide semiconductor materials. For example, an active zone 108 may be arranged between the first and second semiconductor layers 110, 105. The active zone 108 may comprise, for example, a pn junction, a double heterostructure, a single quantum well structure (SQW, single quantum well) or a multiple quantum well structure (MQW, multi quantum well) for generating radiation. The term “quantum well structure” has no meaning with regard to the dimensionality of the quantization. It thus includes, among other things, quantum wells, quantum wires and quantum dots and any combination of these layers. Electromagnetic radiation 15 emitted by the semiconductor component 10 is output via a second main surface 122 of the second semiconductor layer 105, for example. In addition, emitted electromagnetic radiation 15 may be output via side walls of the second semiconductor layer 105. The optoelectronic semiconductor component 10 thus represents a flipchip component in which contacts for contacting the semiconductor layers are arranged on a side of the semiconductor layer stack that faces away from the light-emitting surface 122.

An insulating or passivation layer 117 is arranged over parts of the first metal layer 115 as well as over parts of the second semiconductor layer 105. For example, the passivation layer 117 may contain SiO, SiN, Al₂O₃, SiON, TaₓO_{y}, TiN, AlN, TiₓO_{y} or a combination of these materials. The stoichiometric ratio of the components of the insulating layers described may vary. The passivation layer 117 is arranged, for example, over parts of the optoelectronic “active area”, i.e. the part of the optoelectronic component in which electromagnetic radiation is generated.

For example, the first metal layer 115 may directly adjoin the passivation layer 117.

The optoelectronic semiconductor component further comprises a second metal layer 125 over the second semiconductor layer 105, which is electrically conductively connected to the second semiconductor layer 105. A metal of the second metal layer 125 may be selected from the group comprising rhodium, platinum, palladium, nickel, chromium and gold. In addition, as discussed in connection with the first metal layer 115, adhesion promoting layers may be arranged between the second metal layer 125 and the second semiconductor layer 105. The first and second metal layers each act as a highly reflective mirror layer on the side of the optoelectronic semiconductor component 10 facing away from the emission surface 122. Radiation which is emitted from the active region 108 in the direction of the first main surface 111 of the first semiconductor layer 110 may be reflected to a large extent in the direction of the emission surface 122 by the first and second metal layers 115 and 125.

The stack, which contains the first semiconductor layer 110 and the first metal layer 115, is etched to form a mesa 113. That is, not all parts of the second semiconductor layer 105 are covered with the first semiconductor layer 110, instead there are parts in which a first main surface 106 of the second semiconductor layer 105 is exposed. In these parts, the second semiconductor layer 105 may be electrically contacted. A section of the active zone 108 is exposed in the area of a mesa flank. A part of the passivation layer is arranged over the measurement flank and covers the exposed section of the active zone. Another part of the second metal layer 125 is arranged over the passivation layer 117. The part of the second metal layer 125 covers the passivation layer in the area of the mesa flank and thus the exposed section of the active zone 108. A further part of the second metal layer 125 may be arranged over the first semiconductor layer 110 in such a way that this part overlaps with the first metal layer 115 and forms an overlap region 126 of the metal layers. The fact that the various metal layers 115 and 125 overlap each other ensures a high degree of reflectivity.

According to embodiments shown in FIG. 1A, a lateral positioning of the first metal layer 115 differs by less than 100 nm from the lateral positioning of the structured first semiconductor layer 110. In other words, the first metal layer 115 ends laterally flush with the structured first semiconductor layer 110. When using one of the metals from the group comprising rhodium, platinum, palladium, nickel, chromium and gold, migration of metal ions in the direction of the active area 108 can also be prevented even in case of moisture if the first metal layer 115 is laterally flush with the first structured semiconductor layer 110 and is not, for example, encapsulated by the passivation layer. The term “a lateral positioning of the first metal layer differs by less than 100 nm from the lateral positioning of the structured first semiconductor layer” or “is flush” means in this context that a side wall 115a of the first metal layer 115 is shifted horizontally less than 100 nm from a side wall 110a of the structured first semiconductor layer 110. The horizontal direction may correspond to the x-direction as the upper portion of FIG. 1A illustrates. The size of the shift A may, as illustrated in the upper part of FIG. 1, assume both positive and negative values. In other words, the first metal layer 115 may protrude from the first semiconductor layer 110 by less than 100 nm on each side. Furthermore, the first semiconductor layer may protrude from the first metal layer 115 by less than 100 nm on each side. This can be achieved, for example, if the first metal layer 115 and the first semiconductor layer 110 are etched using the same etching mask. For example, the first semiconductor layer 110 may also be etched using an etching mask that contains the structured first metal layer.

Because the first metal layer 115 is laterally flush with the first structured semiconductor layer 110, a larger part of the chip area may be mirrored, compared to a case in which the area of the metal layer 115 is smaller than the first semiconductor layer 110. By combining the features that the second metal layer covers the passivation layer in the area of the mesa flank and that the lateral positioning of the first metal layer differs by less than 100 nm from the lateral positioning of the structured first semiconductor layer, the reflective surface of the component can be further increased, whereby the efficiency of the optoelectronic semiconductor component is further increased. According to further embodiments, the first metal layer 115 may laterally terminate non-flush with the first structured semiconductor layer 110. For example, part of the passivation layer 117 may be arranged adjacent to part of the first main surface 111 of the first semiconductor layer 110.

For example, a lateral size s of the optoelectronic semiconductor component shown in FIG. 1 may be less than 100 μm, in particular less than 70 μm to less than 10 μm. For example, a lateral extension s may be greater than 1 μm. As shown schematically in FIG. 1A, a layer thickness of the first semiconductor layer 110 may, for example, be smaller than a layer thickness of the second semiconductor layer 105. For example, the first semiconductor layer 110 may have a layer thickness of less than 1 μm, for example less than 200 nm. The second semiconductor layer 105 may have a layer thickness greater than 1 μm, for example greater than 3 μm or greater than 5 μm.

FIG. 1B is a top view of the optoelectronic semiconductor component according to embodiments. As can be seen, the first metal layer 115 forms a first region, the second metal layer 125 forms a second region, and the first metal layer 115 is separated from the second metal layer 125 by the insulating layer 117. For example, the two flat metal layers may each be electrically contacted. A lateral extension s of the optoelectronic semiconductor component is less than 100 μm, for example. Because rhodium, platinum, palladium, gold, nickel or chromium is used as the metal of the first or second metal layer, an excellent reflection property can be provided on the one hand. Furthermore, in contrast to the use of silver as the metal of the first or second metal layer, it is not necessary to encapsulate the metal layer with further layers which would reduce the surface available for reflection. The optoelectronic semiconductor component may thus contain a first or a second metal layer with the corresponding composition. According to further embodiments, however, it is also possible to select both the metal of the first metal layer and the metal of the second metal layer from the group comprising rhodium, platinum, palladium, gold, nickel and chromium.

According to the embodiments illustrated in FIGS. 1A and 1B, the first semiconductor layer 110 may be patterned in such a way that the first semiconductor layer 110 is enclosed by a ring comprising regions in which a first main surface 106 of the second semiconductor layer 105 is not covered by the first semiconductor layer 110. The optoelectronic component may generally have any shape and need not be square.

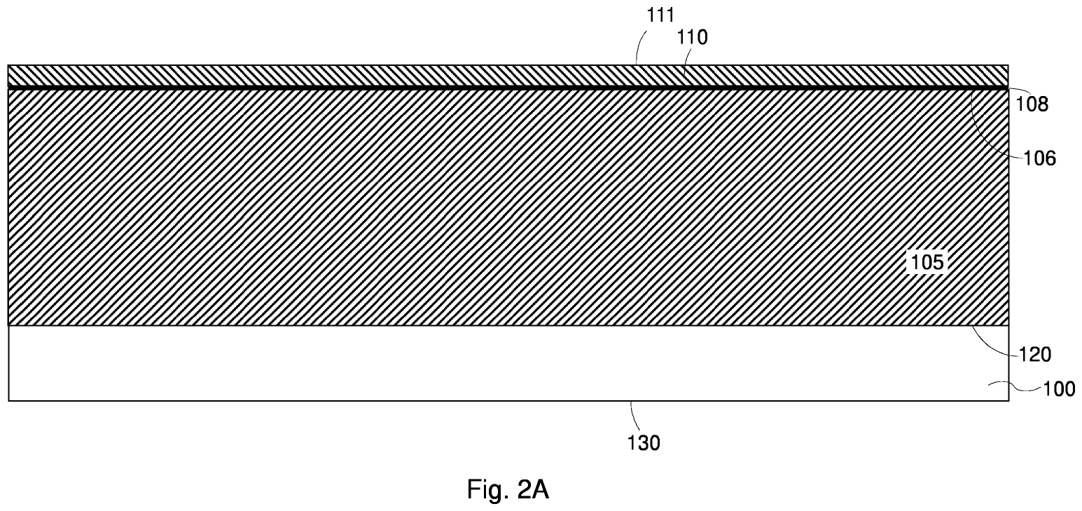

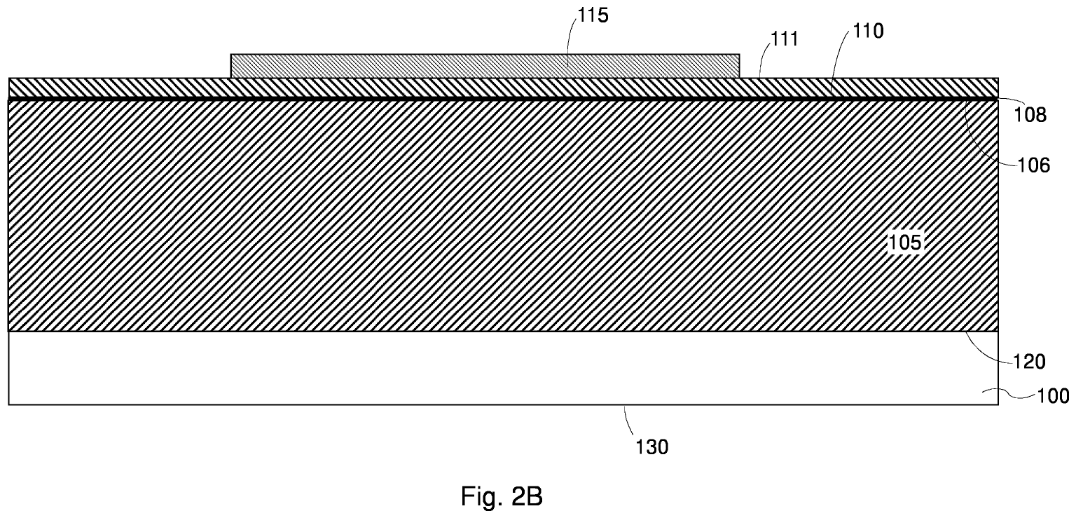

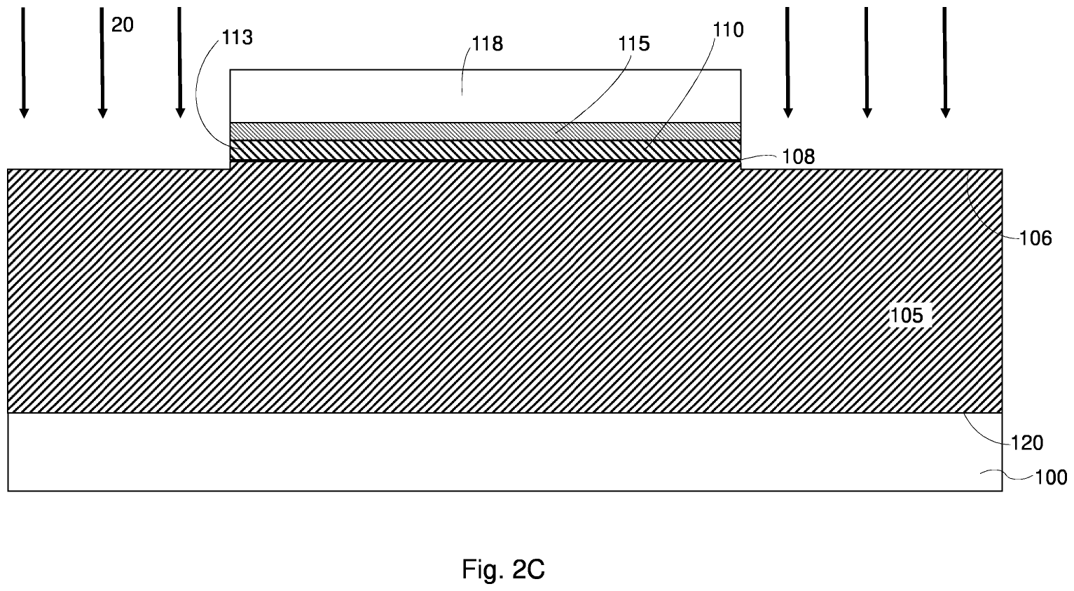

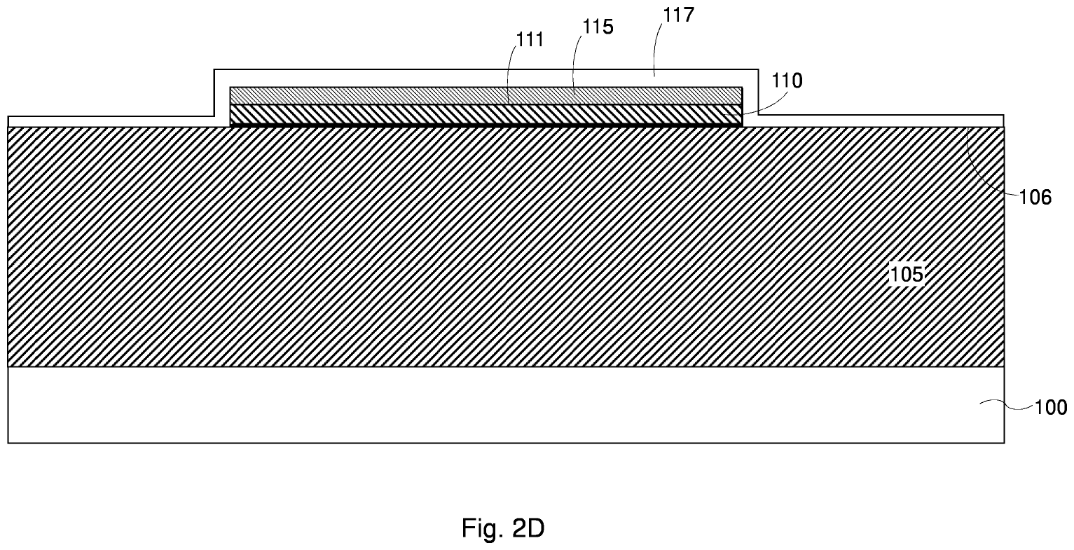

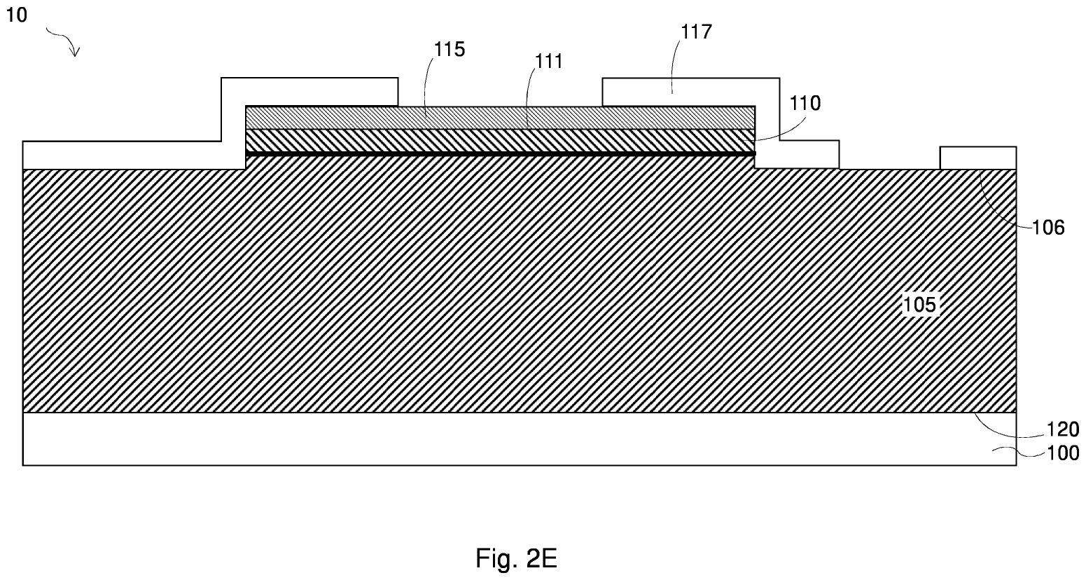

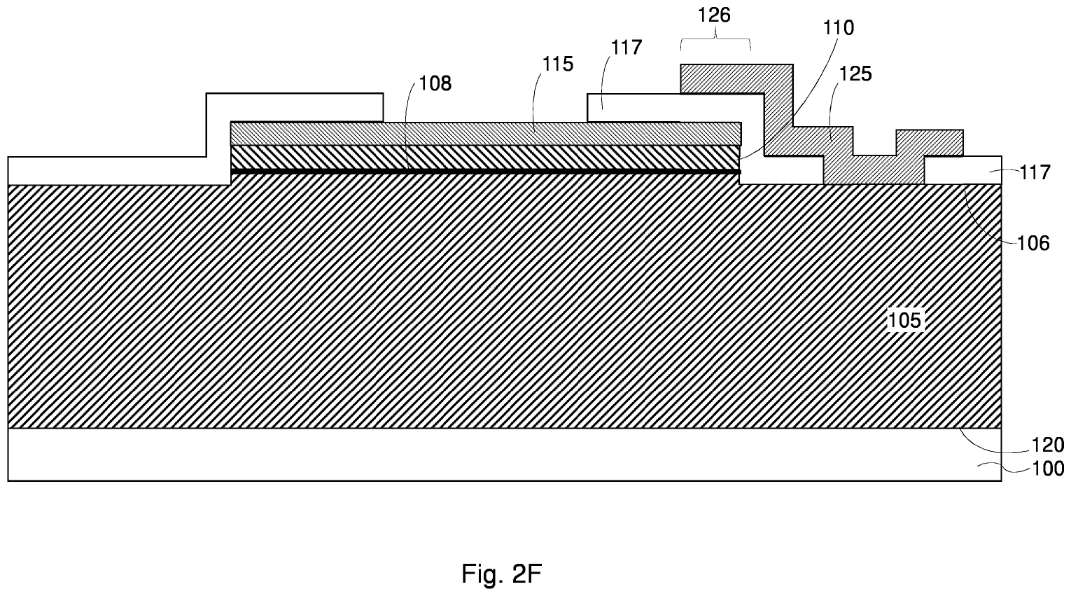

To produce the semiconductor component shown in FIGS. 1A and 1B, the second semiconductor layer 105 of the second conductivity type is grown epitaxially over a first main surface 120 of an insulating growth substrate 100, for example a sapphire substrate 100. After the active zone 108 has been formed, the first semiconductor layer 110 is epitaxially grown over the first main surface of the second semiconductor layer. For example, as a result, the structure shown in FIG. 2A may be obtained. The first semiconductor layer 110 and the second semiconductor layer 105 are arranged over the first main surface 120 of an insulating substrate 100. An active zone 108 is arranged between first and second semiconductor layers 110 and 105.

In a next step, a first metal layer 115 is applied over the first main surface 111 of the first semiconductor layer 110. For example, an adhesion promoting layer with the above-described layer thickness and composition may first be applied, followed by the first metal layer 115. The metal layer may contain rhodium, platinum, palladium, gold, nickel or chromium, for example, or consist of these metals. Furthermore, an additional adhesion promoting layer with the composition described above may be applied. The first metal layer 115 and, if appropriate, the adhesion promoting layers are patterned, for example using photolithographic and etching processes. According to further embodiments, alternatively or additionally, patterned metal layers may also be applied, for example by means of a lift-off method.

As a result, for example, the structure shown in FIG. 2B may be obtained. As can be seen, the first metal layer 115 is arranged over a portion of the first semiconductor layer 110. Additional parts of the first main surface 111 of the first semiconductor layer 110 are not covered.

According to further embodiments, after the first metal layer has been applied, a protective layer 118, for example made of silicon oxide, silicon nitride, photoresist materials, metal oxide such as AlₓO_{y}, TaₓO_{y}, TiₓO_{y}, metal nitride such as TiN, AlN, or other materials, may be applied. For example, an etching process for etching the first semiconductor layer 110 may then be carried out using the patterned first metal layer 115 and, if appropriate, the protective layer 118. In particular, the first metal layer 115 with a layer thickness greater than 500 nm may be used as a hard mask for the etching process. When the structured first metal layer 115 is used as a hard mask for the etching process, it is possible to save area which would be required for correct overlaying during photolithographic patterning of a resist material.

For example, the etching process may be a plasma etching process or a back sputtering process or another suitable process. FIG. 2C shows a cross-sectional view of the workpiece when the etching process 20 is performed. As can be seen, parts of the second semiconductor layer 105 that are not covered with the first metal layer 115 are etched by the etching process. The parts of the second semiconductor layer 105 that are covered with the first metal layer 115 are not etched. As a result, a mesa is etched. An area of the active zone is exposed in the area of a mesa flank and is not covered from the outside.

According to further embodiments, it is also possible to etch the mesa first. The first metal layer 115 is then applied and patterned, or applied already patterned.

An insulating or passivation layer 117 is then applied over the resulting surface. The passivation layer covers parts of the first main surface 106 of the second semiconductor layer 105 and the first metal layer 115. Furthermore, the passivation layer 117 covers at least a part of the exposed area of the active zone 108. For example, the passivation layer 117 may cover the entire mesa flank. For example, the passivation layer 117 may contain SiO, SiN, Al₂O₃, SiON, TaₓO_{y}, TiN, AlN, TiₓO_{y} or a combination of these materials. According to further refinements, the passivation layer 117 may have a layer stack made up of several insulating layers. Layer thickness of the passivation layer may, for example, range from 10 to 500 nm. However, it is also possible for the layer thickness to be less than 10 nm or greater than 500 nm.

Openings may then be defined in the insulating layer 117, for example using photolithographic methods. FIG. 2E shows a cross-sectional view of an example of a resulting optoelectronic semiconductor device. As can be seen, part of the first metal layer 115 is not covered. Furthermore, part of the first main surface 106 of the second semiconductor layer 105 is not covered. Other parts of the optoelectronic semiconductor component 10 are covered by the insulating layer 117.

A second metal layer 125 is then applied and patterned. For example, the metal of the second metal layer may also be selected from the group comprising rhodium, platinum, palladium, gold, nickel and chromium. The application of the second metal layer may initially include the application of an adhesion promoting layer between the second semiconductor layer 105 and the second metal layer 125, as discussed in connection with the first metal layer 115. For example, the second metal layer 125 may be applied over the entire area and then patterned using a suitable patterning process, which may include photolithographic and etching processes. An example of a result that can be obtained is the structure shown in FIG. 2F.

After removing the growth substrate 100, the structure shown in FIG. 1A can be obtained.

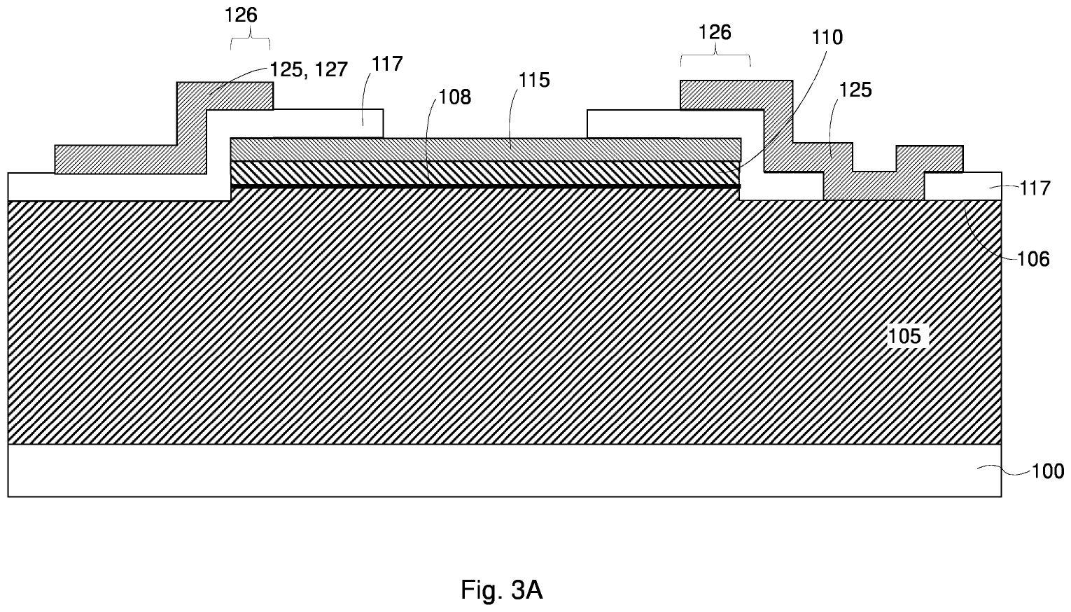

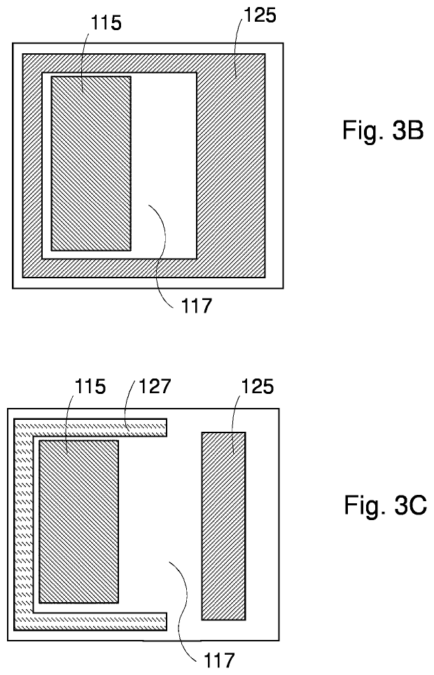

FIG. 3A shows a vertical cross-sectional view of embodiments with a mirror layer 127. As shown, the optoelectronic component 10 may additionally contain a mirror layer 127 made of a metal selected from the group comprising rhodium, platinum, palladium, gold, nickel and chromium, wherein the mirror layer covers other parts of the surface of the optoelectronic component. According to further embodiments, this mirror layer 127 may be isolated from the second metal layer 125. Alternatively, it may be connected to it in an electrically conductive manner and thus form part of the second metal layer 125. As can also be seen, the mirror layer 127 is arranged over the insulating or passivation layer 117. For example, the mirror layer 127 may directly adjoin the insulating or passivation layer 117. Additional parts of the embodiments presented in FIG. 3A are similar to the parts presented in FIGS. 1A and 1B.

FIG. 3B is a top view of the optoelectronic semiconductor component 10 according to embodiments. As can be seen, the second metal layer 125 is formed in such a way that it surrounds the first metal layer 115 in the shape of a ring. That is, according to embodiments, the one shown in FIG. 3A mirror layer 127 shown is electrically conductively connected to the second metal layer 125 and thus itself represents part of the second metal layer 125. The insulating layer 117 insulates the second metal layer 125 from the first metal layer 115.

FIG. 3C is a horizontal cross-sectional view of the optoelectronic semiconductor device according to further embodiments. As can be seen, the mirror layer 127 is electrically separated from the second metal layer 125. The mirror layer 127 surrounds the first metal layer 115 on three sides of the first metal layer 115.

By arranging the mirror layer 127 or the second metal layer 125 as shown in FIGS. 3B and 3C, so that three sides of the first metal layer 115 are enclosed by the mirror layer 127 or the second metal layer 125, a larger part of the generated light can be reflected. The efficiency of the optoelectronic component is increased accordingly. The optoelectronic semiconductor component does not have to be square but may have any shape.

In the optoelectronic semiconductor component illustrated in FIG. 3C, the feature that a metallic mirror layer 127 electrically separated from the second metal layer covers the passivation layer in the area of the mesa flank is thus realized.

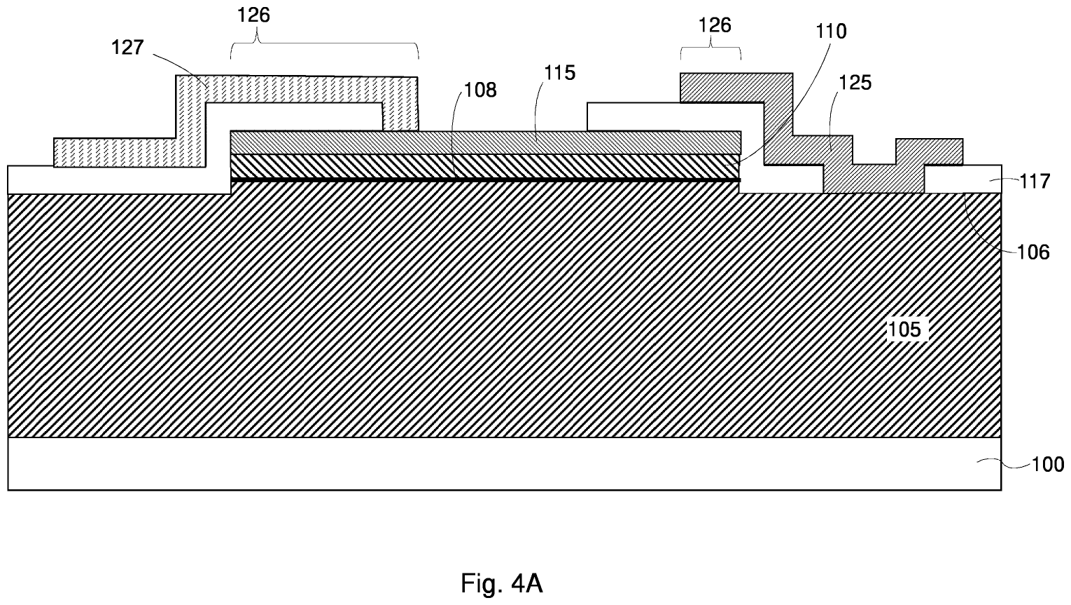

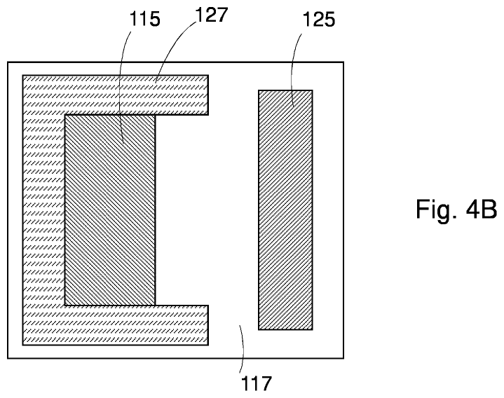

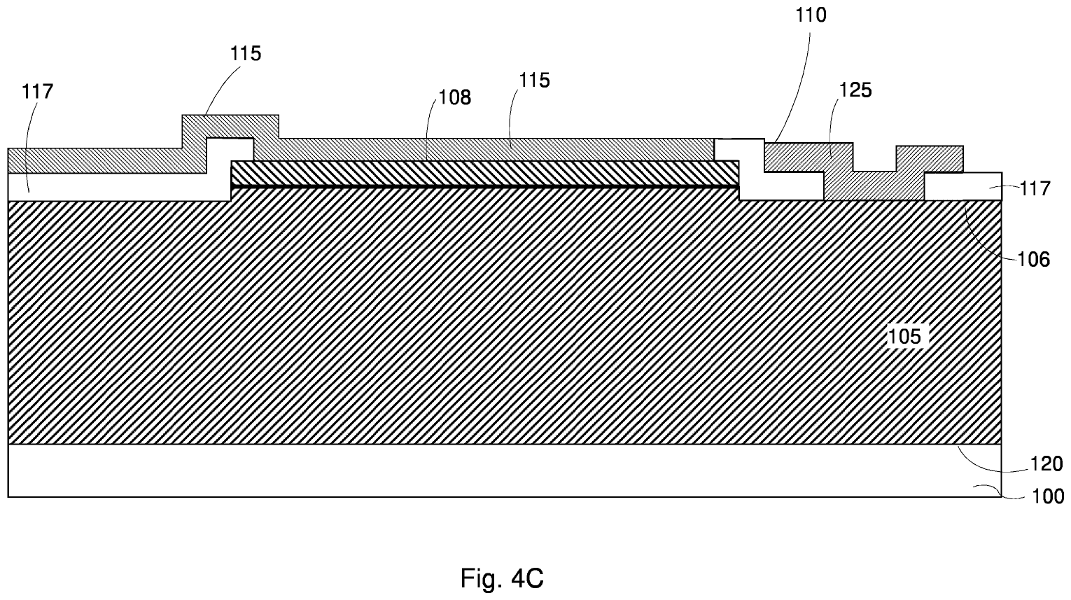

According to further embodiments shown in FIG. 4A, it is possible to connect the mirror layer 127 to the first metal layer 115, so that the mirrored area can be enlarged further. According to embodiments, the optoelectronic component comprises a first metal layer 115, which is arranged over the first semiconductor layer 110 and is connected to it in an electrically conductive manner. The second metal layer 125 is connected to the second semiconductor layer 105 in an electrically conductive manner and is furthermore partly arranged above the insulating layer 117. The mirror layer 127 is arranged at least partially above the insulating layer 117 and connected to the first metal layer 115. As a result, the proportion of the reflective surface of the optoelectronic semiconductor component can be greatly increased. According to embodiments, the first metal layer 115 may directly adjoin the insulating or passivation layer 117. Additionally or alternatively, the mirror layer 127 may directly adjoin the insulating or passivation layer 117.

In the optoelectronic semiconductor component shown in FIG. 4A, the feature that the first metal layer 115, 127 cover the passivation layer 117 in the area of the mesa flank is thus realized.

Since a metal of the first metal layer, the second metal layer and the mirror layer is selected from the group comprising rhodium, platinum, palladium, gold, nickel and chromium, improved stability of the corresponding metal layer and thus improved reliability of the layer can be provided without the need for a space-consuming encapsulation of the layer. Accordingly, a metallic layer may be provided over a large part of the second main surface 106 of the second semiconductor layer or the first main surface 111 of the first semiconductor layer 110, leading to high reflectivity.

FIG. 4B is a top view of the optoelectronic semiconductor component. As can be seen, the proportion of the area of the optoelectronic component that is covered with reflective material is increased.

As illustrated in FIGS. 3A to 4B, the first semiconductor layer 110 of the optoelectronic semiconductor component may be patterned in such a way that the first semiconductor layer 110 is surrounded by a ring comprising areas in which a first main surface 106 of the second semiconductor layer 105 is not covered by the first semiconductor layer.

Furthermore, the first metal layer 115 may be at least partially surrounded by the second metal layer 125. According to further embodiments, the first metal layer 115 may be at least partially surrounded by a combination of second metal layer 125 and mirror layer 127. “At least partially” in this case means that the second metal layer 125 or the combination of second metal layer 125 and mirror layer 127 may be interrupted in sections. For example, an insulating material may be arranged between the conductive sections. According to embodiments, a larger proportion of the area that surrounds the structured first metal layer may be covered by the second metal layer 125 or a combination of second metal layer 125 and mirror layer 127 than by insulating material 117. According to further embodiments, “at least partially” may mean that the second metal layer 125 or the combination of second metal layer 125 and mirror layer 127 is arranged on at least two sides of the structured first metal layer 115.

FIG. 4C shows an embodiment in which parts of the passivation layer 117 in contact with the first semiconductor layer 110 are formed. For example, this may be realized in that after the mesa has been patterned, the passivation layer 117 is formed and patterned. The first metal layer 115 and the second metal layer are then formed and patterned. For example, this may be done through joint process steps. The first metal layer 115 may be formed in such a way that it covers the passivation layer in the area of the mesa flank. The second metal layer 125 may be patterned in a different way than is shown in FIG. 4C.

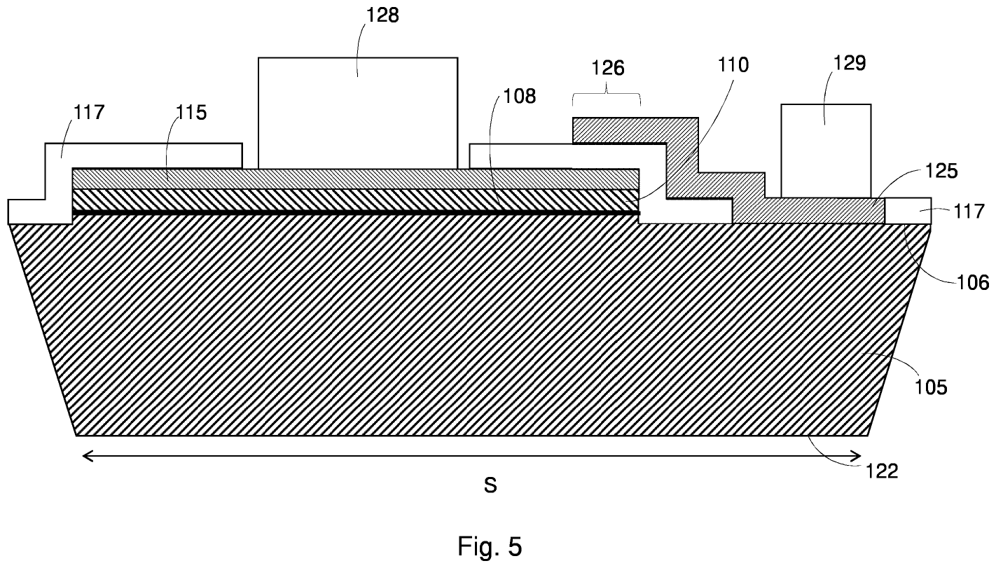

FIG. 5 shows a cross-sectional view of an optoelectronic semiconductor component in accordance with further embodiments. Starting from the structure shown in FIG. 2F, 3A or 4A, the growth substrate 100 may be removed from the second main surface of the second semiconductor layer 105, so that the second main surface 122 is not covered. In addition, a first connection element 128 may be formed in contact with the first metal layer 115. Furthermore, a second connection element 129 may be formed in contact with the second metal layer 125. For example, a 200 to 300 nm thick gold layer may be applied in order to form the first connection element 128 and the second connection element 129. Alternatively, the first and second connection elements 128 and 129 may also be formed in a different way, for example by gluing or applying an anisotropically conductive film. The second semiconductor layer 105 may have a different vertical cross section than that shown. For example, the flank angles may be different than shown.

In this way, the first metal layer 115 and the second metal layer 125, in addition to their function as a mirror layer, may be used in a simple manner as current-carrying layers. Additional metallization layers for contacting may be dispensed with in this way, for example. The mirror layer thus also fulfills the functionality of a contact layer.

For example, a lateral extension of the first connection element 128 may be smaller than a lateral extension of the first metal layer 115. Furthermore, a lateral extension of the second connection may be smaller than a lateral extension of the second metal layer 125.

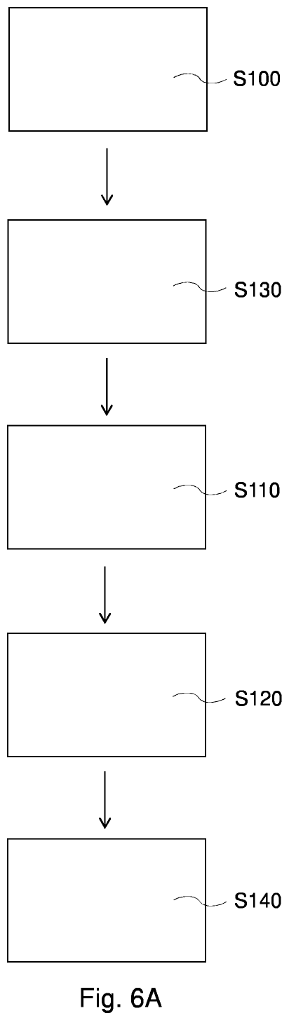

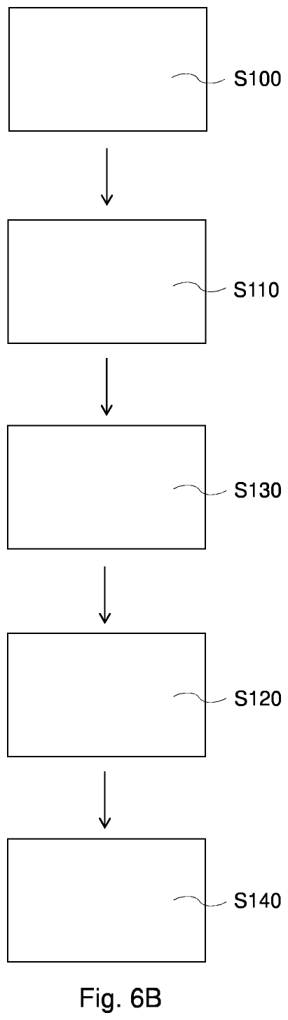

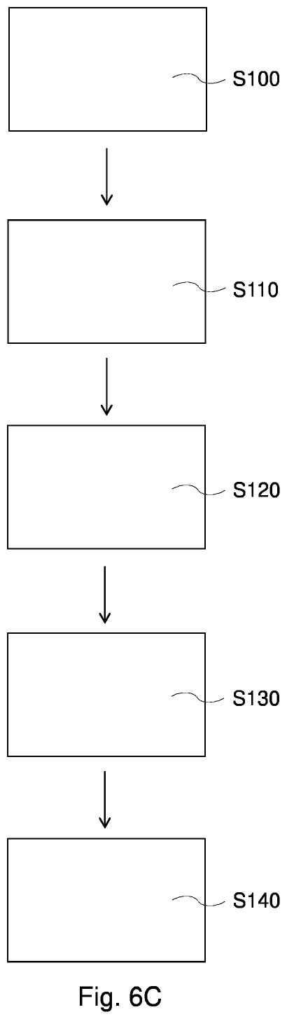

The FIGS. 6A to 6B each summarize procedures according to embodiments.

A method for producing an optoelectronic semiconductor component comprises the formation (S100) of a semiconductor layer stack from a first semiconductor layer of a first conductivity type, a second semiconductor layer of a second conductivity type and an active zone, the active zone being arranged between the first and second semiconductor layer. The method further comprises structuring a mesa (S110) so that parts of the second semiconductor layer are not covered by the first semiconductor layer and a section of the active zone is exposed in the area of a mesa flank. The method further comprises forming a passivation layer (S120) over parts of the first semiconductor layer, over parts of the second semiconductor layer and over the exposed portion of the active area, forming (S130) a first metal layer which is electrically connected to the first semiconductor layer and forming (S140) a second metal layer that is electrically connected to the second semiconductor layer. The second metal layer covers the passivation layer in the area of the mesa flank. A composition of the first metal layer adjacent to the first semiconductor layer is constant in a horizontal direction.

According to further embodiments, the first metal layer or a metallic mirror layer electrically separated from the second metal layer covers the passivation layer in the area of the mesa flank.

As illustrated in FIG. 6A, the first metal layer may be formed (S130) after the semiconductor layer stack has been formed (S100). A mesa is then patterned (S110). Then the passivation layer is formed (S120) and the second metal layer is formed (S140).

As shown in FIG. 6B, after the semiconductor layer stack has been formed (S100), the mesa may be patterned (S110). The first metal layer is then formed (S130). Subsequently, the passivation layer is formed (S120) and the second metal layer is formed (S140).

As shown in FIG. 6C, after the semiconductor layer stack has been formed (S100), the mesa may be patterned (S110). The passivation layer is then formed (S120). The first metal layer is then formed (S130) and the second metal layer is formed (S140). In this case, for example, the first and second metal layers may also be produced by joint metal layer deposition processes.

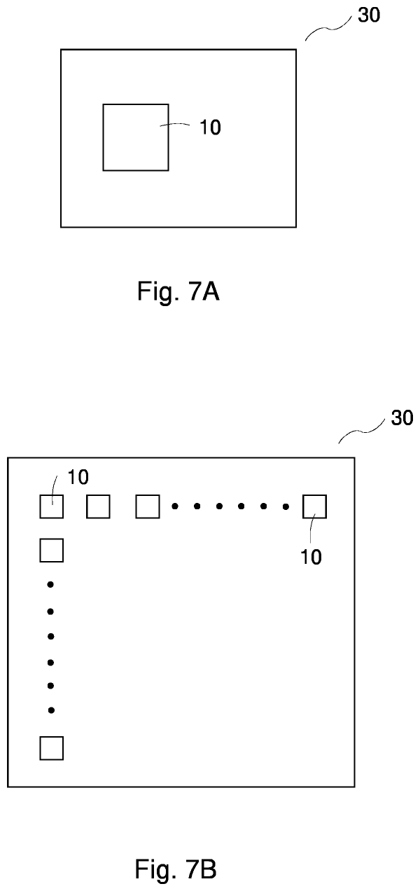

FIG. 7A shows an optoelectronic device according to embodiments. The optoelectronic device 30 comprises the optoelectronic semiconductor component 10 described. As has been described, a lateral extension of the optoelectronic semiconductor component may be further reduced. Accordingly, it is possible to arrange optoelectronic semiconductor components very densely. Accordingly, the optoelectronic device may, for example, be an arrangement with a large number of pixels with small spacing.

FIG. 7B shows a schematic view of an optoelectronic device 30 comprising a multitude of optoelectronic components 10. For example, the optoelectronic components 10 may be arranged in rows and columns. However, any other arrangement pattern is also conceivable. For example, the individual optoelectronic components or semiconductor chips may have a hexagonal shape.

For example, in this case the individual chips may be arranged in such a way that the chips in adjacent rows are offset from one another, so that a greater packing density can be achieved. Furthermore, the individual optoelectronic components or semiconductor chips may be arranged in accordance with an RGB arrangement pattern.

The optoelectronic device may be, for example, a display device with several million pixels. Other examples of the optoelectronic device 30 are lighting devices, for example for vehicles, for example a headlight with pixelated light or general lighting devices with small light sources for which further miniaturization of the individual light elements is desired.

Although specific embodiments have been illustrated and described herein, those skilled in the art will recognize that the specific embodiments shown and described may be replaced by a variety of alternative and/or equivalent configurations without departing from the scope of the claims. The application is intended to cover any adaptations or variations of the specific embodiments discussed herein. Therefore, the invention is to be limited only by the claims and their equivalents.

### LIST OF REFERENCE NUMERALS

10 Optoelectronic semiconductor component
15 emitted electromagnetic radiation
20 etching process
30 optoelectronic device
100 substrate
105 second semiconductor layer
106 first main surface of the second semiconductor layer
108 active zone
110 first semiconductor layer
110a sidewall of the first semiconductor layer
111 first main surface of the first semiconductor layer
113 mesa
115 first metal layer
115a side wall of the first metal layer
117 passivation layer
118 protective layer
120 first main surface of the substrate
122 second main surface of the second semiconductor layer
125 second metal layer
126 overlap area of the metallic layers
127 mirror layer
128 first connection element
129 second connection element
130 second main surface of the substrate

1. An optoelectronic semiconductor component comprising:
a first semiconductor layer of a first conductivity type, a second semiconductor layer of a second conductivity type, and an active zone wherein:
the first semiconductor layer is arranged over the second semiconductor layer, the active zone is arranged between the first and second semiconductor layer and the first semiconductor layer and the second semiconductor layer are patterned to form a mesa so that parts of the second semiconductor layer are free from the first semiconductor layer and a portion of the active zone is exposed in the area of a mesa flank;
a passivation layer arranged over parts of the first semiconductor layer and over parts of the second semiconductor layer and over the exposed portion of the active zone;
a first metal layer electrically connected to the first semiconductor layer, and a second metal layer electrically connected to the second semiconductor layer;
wherein the second metal layer covers the passivation layer in the area of the mesa flank and a composition of the first metal layer adjacent to the first semiconductor layer is constant in a horizontal direction; and
the first metal layer directly adjoins the first semiconductor layer and a lateral positioning of the first metal layer differs by less than 100 nm from the lateral positioning of the patterned first semiconductor layer.

2. The optoelectronic semiconductor component according to claim 1, wherein a metal of the first or second metal layer is selected from the group consisting of rhodium, platinum, gold, nickel, chromium, palladium, or combinations thereof.

3. The optoelectronic semiconductor component according to claim 1, wherein a metal of the first metal layer comprises rhodium, the second metal layer comprises palladium, or combinations thereof.

4. (canceled)

5. The optoelectronic semiconductor component according to claim 1, wherein a horizontally extending part of the second metal layer is arranged over the first metal layer.

6. The optoelectronic semiconductor component according to any claim 1, further comprising a metallic mirror layer electrically insulated from the second semiconductor layer and where the second metal layer is arranged over part of the second semiconductor layer.

7. The optoelectronic semiconductor component according to claim 6, wherein a metal of the metallic mirror layer is selected from the group consisting of rhodium, platinum, gold, nickel, chromium, palladium, or combinations thereof.

8. The optoelectronic semiconductor component according to claim 6, wherein the metallic mirror layer is connected to the first metal layer.

9. The optoelectronic semiconductor component according to claim 1, wherein the first metal layer is laterally at least partially surrounded by the second metal layer, the metallic mirror layer, or a combination thereof.

10. An optoelectronic semiconductor component, comprising:
a first semiconductor layer of a first conductivity type, a second semiconductor layer of a second conductivity type, and an active zone, wherein:
the first semiconductor layer is arranged over the second semiconductor layer, the active zone is arranged between the first and second semiconductor layer and the first semiconductor layer and the second semiconductor layer are patterned to form a mesa so that parts of the second semiconductor layer are free from the first semiconductor layer and a portion of the active zone is exposed in the area of a mesa flank;
a passivation layer arranged over parts of the first semiconductor layer and over parts of the second semiconductor layer as well as over the exposed portion of the active zone;
a first metal layer electrically connected to the first semiconductor layer; and
a second metal layer electrically connected to the second semiconductor layer, and wherein the first metal layer or a metallic mirror layer electrically separate from the second metal layer covers the passivation layer in the area of the mesa flank.

11. The optoelectronic semiconductor component according to claim 10, wherein a metal of the first metal layer comprises rhodium, the second metal layer comprises palladium, or combinations thereof.

12. The optoelectronic semiconductor component according to claim 10, wherein a lateral positioning of the first metal layer differs by less than 100 nm from the lateral positioning of the patterned first semiconductor layer.

13. The optoelectronic semiconductor component according to claim 10, wherein the metallic mirror layer is connected to the first metal layer.

14. The optoelectronic semiconductor component according to claim 13, wherein part of the metallic mirror layer is arranged over part of the second semiconductor layer.

15. The optoelectronic semiconductor component according to claim 10, wherein a lateral size of the optoelectronic semiconductor component is less than 70 μm.

16. A method for producing an optoelectronic semiconductor component, comprising:
forming a semiconductor layer stack comprising a first semiconductor layer of a first conductivity type, a second semiconductor layer of a second conductivity type and an active zone, the active zone being arranged between the first and second semiconductor layers;
patterning a mesa so that parts of the second semiconductor layer are free from the first semiconductor layer and a portion of the active zone is exposed in the area of a mesa flank;
forming a passivation layer over parts of the first semiconductor layer, over parts of the second semiconductor layer and over the exposed portion of the active zone; forming a first metal layer electrically connected to the first semiconductor layer;
forming a second metal layer electrically connected to the second semiconductor layer,
wherein the second metal layer covers the passivation layer in the area of the mesa flank and a composition of the first metal layer adjacent to the first semiconductor layer is constant in a horizontal direction,
wherein the first metal layer directly adjoins the first semiconductor layer and a lateral positioning of the first metal layer differs by less than 100 nm from the lateral positioning of the patterned first semiconductor layer.

17. (canceled)

18. The method according to claim 16 or 17, further comprising:
etching a part of the first metal layer to obtain a patterned first metal layer;
wherein the first semiconductor layer is patterned using the patterned first metal layer as an etching mask.

19-20. (canceled)
